(19) United States
(12) Patent Application Publication
(10) Pub. No.: US 2011/0232750 A1
(43) Pub. Date: Sep. 29, 2011

(54) SOLAR CELL MODULE AND MANUFACTURING METHOD THEREOF

(75) Inventor: Kun-Chih Lin, Tainan (TW)

(73) Assignee: AURIA SOLAR CO., LTD., Tainan (TW)

(21) Appl. No.: 13/150,993

(22) Filed: Jun. 1, 2011

(30) Foreign Application Priority Data
May 18, 2011 (TW) 100117382

(51) Int. Cl. H01L 31/02; H01L 31/18; H01L 31/0232

(52) U.S. Cl. 136/256; 438/64; 438/65; 257/E31.127; 257/E31.11

(57) ABSTRACT

A solar cell module includes a substrate having a thin-film layer patterned in a manner to form with a split window and a solar cell disposed on the substrate. The solar cell includes plurality of material layers and a plurality of split ways corresponding to the material layers. The scope of the split window is constituted by at least one of the split ways.

### CROSS-REFERENCE TO RELATED APPLICATIONS

This non-provisional application claims priority under 35 U.S.C. §119(a) on Patent Application No. 100117382 filed in Taiwan, R.O.C. on May 18, 2011, the entire contents of which are hereby incorporated by reference.

### BACKGROUND OF THE INVENTION

1. Field of the Invention

The present invention relates to a solar cell module and a manufacturing method thereof, and more particularly to a solar cell module, which includes a thin-film layer provided with functional property thereof.

2. Description of the Prior Art

As the technology advances and development in the economy, human beings require more and more energy for their modern development. The naturally found crude petroleum, natural gas and coal, upon which, human beings rely heavily are gradually in shortage or run out as days gone by. So that the development and utilization of renewable energy that cause no environmental pollution have drawn the great attention for the human beings. As far as renewable energy is concerned, a solar cell has the features of ever-lasting energy, and can provide more than ten times of the energy amount the world requires presently. Therefore, we have to find a way how to effectively utilize the solar energy and making wide research is the main focus of the present day problem.

Generally speaking, a conventional solar cell module includes a solar cell disposed on a substrate. The solar cell is usually composed of two electrode layers sandwiching an active layer therebetween. During fabrication of the conventional solar cell module, the electrode layers and the active layer must usually undergo several splitting process in order to form several units of solar cell. The splitting process includes melting action (patterning) utilizing the laser beam.

In order to enhance the functional property of the solar cell module, a few functional layers are provided between the substrate and the solar cell, such as a reflective layer for raising the functional property of the solar energy.

Due to presence of the functional layers, the laser beam is unable penetrate into the solar via the substrate, but can rather penetrate into the solar cell from a sidewise direction thereof. Thus, during the fabrication process, the functional layer is formed by adding and adjusting the doping materials depending on the different functional property of the functional layers, hence causing complicated doping processes. In addition, since the laser beam can penetrate into the solar cell from sidewise direction, the melting waste is often left and is deposited at the split ways in the functional layers. Thus, the waste can not be easily removed from the split ways, which, in turn, results in untimely and undesired ruin of the solar cells.

Due to the above-mentioned facts, the inventor of the present invention feels that a fabricating method and a new solar cell module should be developed, so that the functional property of the solar cell can be maintained while causing no complication process in the fabricating method of the solar cell.

### SUMMARY OF THE INVENTION

Therefore, in the prior art technology, when the solar cell includes a thin-film layer having functional property, the melting of the materials caused by the laser beam includes complicated steps owing to the reason that the laser beam cannot enter into the solar cell from sidewise of the substrate. The laser beam nevertheless enters into the solar cell from sidewise direction thereof such that the waste caused due to melting operation is left behind in the split way, which, in turn, results in untimely ruin of the solar cell. Since the laser beam must enter the solar cell from sidewise direction, the laser beam should possess different parameterization owing to different split ways in the solar cell, thereby causing complicated steps in the splitting operation due to presence of the thin-film layer having functional property.

In order to solve the aforesaid problems, the main object of the present invention is to provide a fabricating method and solar cell module, in which, the thin-film layer disposed on a substrate is formed with a split window. Then, a solar cell is disposed on the substrate. During formation of the solar cell, high energy beam is allowed to penetrate through the split window in order to form different split ways in the solar cell.

The solar cell module of the present invention accordingly includes a substrate and a solar cell. The substrate includes a thin-film layer formed with a split window. The solar cell is disposed on the substrate, and includes a plurality of material layers and a plurality of split ways corresponding to the material layers such that the scope of the split window is constituted by at least one of the split ways.

Preferably, the substrate includes a transparent substrate with the thin-film layer being disposed on the transparent substrate.

In one embodiment, the substrate further includes a buffer layer disposed on the transparent substrate in such a manner the buffer layer is sandwiched between the thin-film layer and the transparent substrate.

In one embodiment, the material layers includes a first electrode layer, an active layer and a second electrode layer. Preferably, the first electrode layer is formed with a first split way. The active layer is formed with a second split way while the second electrode layer is formed with a third split way.

Preferably, the thin-film layer includes at least one colored film, an anti-reflective film, a protection film and a reflective film.

The method for fabricating the solar cell module of the present includes the steps of: firstly preparing a substrate including a transparent substrate and a thin-film layer formed on the transparent substrate; conducting splitting process on the thin-film layer such that the thin-film layer is formed with a split window via which the transparent substrate is exposed; and disposing a solar cell on the substrate, the solar cell including a plurality of material layers and a plurality of split ways corresponding to the material layers, wherein, at least one of the split ways is formed due to melting action in the material layers when a high energy beam passes through the split window of the thin-film layer.

The solar cell module fabricating method further includes minor steps of disposing the thin-film layer on the transparent substrate and patterning the thin-film layer in order to form the split window in the thin-film layer.

In one embodiment, the material layers formed by disposing sequentially a first electrode layer, an active layer and a second electrode layer over the substrate. During the formation operation, high energy beam is allowed to penetrate through the split window in the thin-film layer in order to melt a portion of the material layers, thereby forming at least one of the split ways.

In one embodiment, the thin-film layer includes a colored film, an anti-reflective film, a protection film or a reflective film.

Preferably, laser beam is utilized as the high energy beam in the present invention.

As explained above, when compared to the prior art solar cell module, the fabricating method and solar cell module of the present invention includes a thin-film layer patterned in such a manner to form with a split window such that the high energy is allowed to penetrate via the split window into the solar cell, thereby melting the material layers in such a manner to form with a plurality of split ways.

Since the high energy beam enters the solar cell via the split window in the thin-film layer, a portion material of the solar cell is pushed (squeezed) outward due to melting, which, in turn, causes easily cleaning of the split ways and hence no waste is left over in those split ways in the material layers, hence increasing the production rate of fine solar cell. In addition, since the thin-film layer is patterned to form with the split window, the high energy beam enters into the solar cell via the split window along the same entrance direction in order to cause the melting for formation of the split ways. In other words, there is no need to change the entering direction of the energy beam into the solar cell, hence increasing the production rate of the solar cell module.

### BRIEF DESCRIPTION OF THE DRAWINGS

Other features and advantages of this invention will become more apparent in the following detailed description of the preferred embodiments of this invention, with reference to the accompanying drawings, in which:

FIG. 1 shows a cross-sectional view illustrating formation of a substrate in the first embodiment of a solar cell module of the present invention;

FIG. 2 shows a cross-sectional view illustrating formation of a thin-film layer and a first electrode layer in the first embodiment of the solar cell module of the present invention;

FIG. 3 shows a cross-sectional view illustrating formation of an active layer in the first embodiment of the solar cell module of the present invention;

FIG. 4 shows a cross-sectional view illustrating formation of a second electrode and a third split way in the first embodiment of the solar cell module of the present invention;

FIG. 5 shows a cross-sectional view of the second embodiment of the solar cell module of the present invention;

FIG. 6 shows a cross-sectional view of the third embodiment of the solar cell module of the present invention;

FIG. 7 shows a cross-sectional view of the fourth embodiment of the solar cell module of the present invention;

FIG. 8 shows a cross-sectional view of the fifth embodiment of the solar cell module of the present invention; and

FIG. 9 shows a cross-sectional view of the sixth embodiment of the solar cell module of the present invention.

### DETAILED DESCRIPTION OF THE PREFERRED EMBODIMENTS

The fabricating method and solar cell module provided according to the present invention is widely applied in several types of solar cell assemblies having functional property of a thin-film layer. By forming a split window in the thin-film layer in such a manner that entrance of the high energy beam is not affected due to presence of the thin-film layer. Of course, due to different types and designs in fabrication and formation, a few embodiments are illustrated in the following paragraphs.

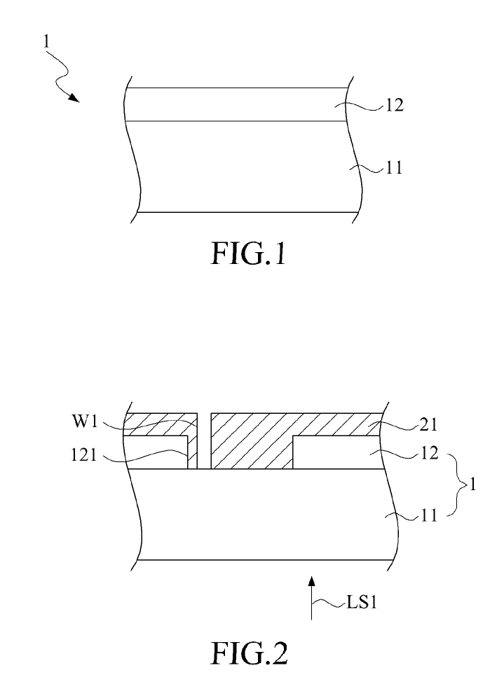

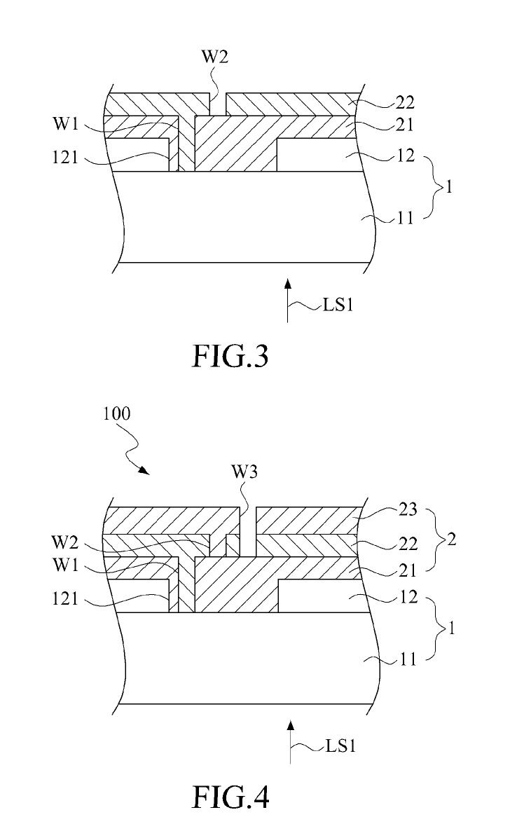

Referring to FIGS. 1 and 3, wherein FIG. 2 shows a cross-sectional view illustrating formation of a thin-film layer and a first electrode layer in the first embodiment of the solar cell module of the present invention while FIG. 3 shows a cross-sectional view illustrating formation of an active layer in the first embodiment of the solar cell module of the present invention. As illustrated, the fabrication of a substrate 1 in the solar cell module 100 (see FIG. 4) accordingly includes: firstly a thin-film layer 12 is disposed on a transparent substrate, such as a glass substrate 11, after which, a high energy beam LS 1 is allowed to penetrate through the glass substrate 11 in order form a split window 121 in the thin-film layer 12. Afterwards, a first electrode layer 21 is disposed on the substrate 1 such that the first electrode layer 21 overlaps the split window 121 in the thin-film layer 12 and the glass substrate 11. Finally, the high energy beam LS1 is allowed to penetrate through the first electrode layer 21, thereby forming a first split way w1 in the first electrode layer 21.

FIG. 3 shows a cross-sectional view illustrating formation of an active layer 22 in the first embodiment of the solar cell module of the present invention. As illustrated, the active layer 22 is disposed on the first electrode layer 21 simultaneously filling the entire space of the first split way w1 in the first electrode layer 21. The high energy beam LS1 is then allowed to penetrate through the glass substrate 11, the split window 121 and the first electrode layer 21 in order to split the active layer 22 such that the latter is formed with a second split way w2.

FIG. 4 shows a cross-sectional view illustrating formation of a second electrode 23 and a third split way w3 in the first embodiment of the solar cell module of the present invention. As illustrated, a second electrode layer 23 is disposed on the active layer 22 and the high energy beam LS1 is allowed to penetrate through the glass substrate 11, the split window 121 and the first electrode layer 21 in order to split the active layer 22 and the second electrode layer 23 simultaneously filling the entire space of the second split way w2, thereby forming a third split way w3. Under this condition, the first, second and third split ways (w1,w2,w3) cooperatively define the solar cell 2.

As described above, in the method for fabricating the solar cell module 100 of the present invention, the thin-film layer 12, the first electrode layer 2, the active layer 22 and the second electrode layer 23 are formed by chemical vapor deposition (CVD). Preferably, the CVD can be (Plasma-Enhanced CVD, PECVD). However, the formation process should not be limited only to those mentioned above.

The thin-film layer 12 includes at least one colored film, an anti-reflective film, a protection film or a reflective film. The colored film mentioned herein is adapted to absorb or reflects the incident light beam of a specific wavelength, for instance, the colored film can reflect the red light beam with wavelength of 669 nm. The materials for formation of the colored film include Silicon, Silicon nitride, Silicon carbonate, Silicon nitride or a combination of any ones of the former. The Silicon, Silicon nitride, Silicon carbonate and Silicon nitride may have different atomic numbers. The anti-reflective film may be a combination multiple films and is adapted to reduce the reflection wavelength ranging from 400 nm to 700 nm. The materials for formation of the anti-reflective film include Silicon oxide, silicon nitride or a combination of any ones of the former. The materials for forming the protection film include Silicon oxide, Silicon nitride, Nitroxide silicon or other waterproof, high rigidity film. The material for formation of the reflective film includes metal or metal oxides.

The materials for forming the first and second electrode layers 221, 23 include TCO (transparent conductive oxide), which can be ITO (indium tin oxide), AZO (Al doped ZnO), or IZO (indium zinc oxide). However, the materials should not be limited only to those mentioned above.

The active layer 22 is composed of a P-type semiconductor layer and N-type semiconductor layer; or P-type semiconductor layer, an intrinsic layer and a N-type semiconductor layer, which are in blanket-stacked structures. The blanket-stacked structure can be multiple blanket-stacked structures. The materials for the active layer 3 include silicon based semiconductor and is composed of compounds from Group IIIA-VA elements, Group IIA-VIA elements or is composed of multiple chemical compounds. However, the limitation should not be restricted only to those elements. The doping materials for the P-type semiconductor layer are selected from Group IIIA elements of the Periodic Table. The Group IIIA consists of Boro or Baron (B) or gallium (Ga), while the Group VA consists of phosphorous (P) or Arsenic (As).

In the method for fabricating the solar cell module of the present invention, laser beam is used as the high energy beam LS 1 in order to split the split ways in the material layers forming a solar cell and its parameters, such as wavelength or functional property, are adjusted depending on the differences of the split ways in the material layers. Since the high energy beam LS1 is adapted to penetrate via the split window 121 into the solar cell 2 so as to conduct the splitting operation. Thus, during the patterning operation or splitting operation, a portion material of the solar cell is pushed outward or squeezed out due to melting, which, in turn, causes easily cleaning of the split ways and hence no waste is left behind in those split ways. In addition, since the thin-film layer is patterned to form with the split window, the high energy beam LS 1 enters into the solar cell 2 via the split window 121 in the same direction in order to cause the melting for formation of the split ways. In other words, there is no need to change the entering direction of the energy beam LS1 into the solar cell 2, hence increasing the production rate of the solar cell module 100.

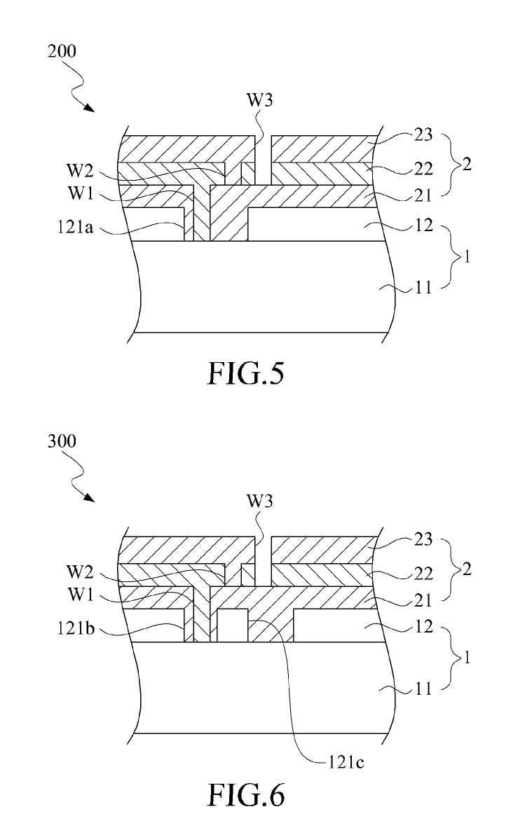

FIG. 5 shows a cross-sectional view of the second embodiment of the solar cell module of the present invention. As illustrated, the solar cell module 200 includes the substrate 1 and the solar cell 2 consisting of a plurality of material layers. The substrate 1 is composed of the glass subtract 11 and the thin-film layer 12. The thin-film layer 12 is disposed on the glass substrate 11 and is formed with the split window 121 a via which the glass substrate 11 is exposed. The solar cell 2 is disposed on the substrate 1, and includes a first electrode layer 21, an active layer 22 and a second electrode layer 23, which cooperatively constituting the material layers. The first electrode layer 21 is disposed on the thin-film layer 12 such that the first electrode layer 21 overlaps the thin-film layer 12 with the split window 121 and the glass substrate 11. The first electrode layer 21 is patterned to form with the first split way w1. The active layer 22 is disposed on the first electrode layer 21 simultaneously filling the entire space of the first split way w1 in the first electrode layer 21. The active layer 22 is patterned to form with the second split way w2. The second electrode layer 23 is disposed on the active layer 22 simultaneously filling the entire space of the second split way w2 in the active layer 22. The second electrode layer 23 is patterned to form with the third split way w3.

The scope of the split window 121a is constituted by the first and second split ways w1, w2.

FIG. 6 shows a cross-sectional view of the third embodiment of the solar cell module of the present invention. As illustrated, the solar cell module 300 includes the substrate 1 and the solar cell 2. The substrate 1 is composed of the glass subtract 11 and the thin-film layer 12. The thin-film layer 12 is disposed on the glass substrate 11, and is patterned to form with two split windows 121b and 121c via which the glass substrate 11 is exposed. The solar cell 2 is disposed on the substrate 1, and includes a first electrode layer 21, an active layer 22, and a second electrode layer 23. The first electrode layer 21 is disposed on the thin-film layer 12 such that the first electrode layer 21 overlaps the thin-film layer 12 with the split window 121b, 121c via which the glass substrate 11 is exposed. The first electrode layer 21 is patterned to form with the first split way w1. The active layer 22 is disposed on the first electrode layer active layer 22 simultaneously filling the entire space of the first split way w1 in the first electrode layer 21. The active layer 22 is patterned to form with the second split way w2. The second electrode layer 23 is disposed on the active layer 22 simultaneously filling the entire space of the second split way w2 in the active layer 22. The second electrode layer 23 is patterned to form with the third split way w3.

Preferably, the scope of the split window 121b is constituted by the first split way w1, the split window 121c and the second split way w2.

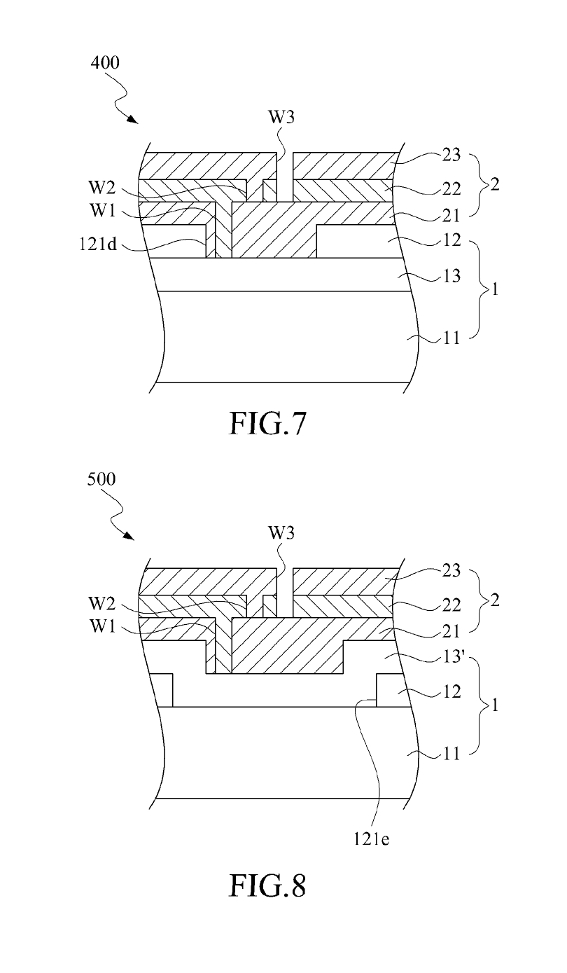

FIG. 7 shows a cross-sectional view of the fourth embodiment of the solar cell module of the present invention. As illustrated, the solar cell module 400 includes the substrate 1 and the solar cell 2. The substrate 1 is composed of the glass subtract 11, the thin-film layer 12 and a buffer layer 13. The buffer layer 13 is disposed on the glass substrate 11 in such a manner that the buffer layer 13 is sandwiched between the thin-film layer 12 and the glass substrate 11. The thin-film layer 12 is patterned to form with a split window 121d via which the buffer layer 13 is exposed. The solar cell 2 is disposed on the substrate 1, and includes the first electrode layer 21, the active layer 22 and the second electrode layer 23. The first electrode layer 21 is disposed on the thin-film layer 12 such that the first electrode layer 21 overlaps the split window 121 d and the buffer layer 13. The first electrode layer 21 is patterned to form with the first split way w1. The active layer 22 is disposed on the first electrode layer active layer 22 simultaneously filling the entire space of the first split way w1 in the first electrode layer 21. The active layer 22 is patterned to form with the second split way w2. The second electrode layer 23 is disposed on the active layer 22 simultaneously filling the entire space of the second split way w2 in the active layer 22. The second electrode layer 23 is patterned to form with the third split way w3.

Preferably, the scope of the split window 121d is constituted by the first split way w1, the second split way w2 and the third split way w3. In addition, the buffer layer 13 can prevent the impurity or dopant, such as sodium (Na) from spreading into the lately formed solar cell 2. The material for formation of the buffer layer 13 consists of Silica, Silicon nitride, nitroxide Silicon or a combination of any ones of the former.

FIG. 8 shows a cross-sectional view of the fifth embodiment of the solar cell module of the present invention. As illustrated, the solar cell module 500 includes the substrate 1 and the solar cell 2. The substrate 1 is composed of the glass subtract 11, the thin-film layer 12 and the buffer layer 13′. The thin-film layer 12 is disposed on the glass substrate 11 and is patterned to form with the split window 121e for exposing the glass substrate 11. The buffer layer 13′ is disposed on the glass substrate 11 in such a manner that the buffer layer 13 is sandwiched between the thin-film layer 12 and the glass substrate 11 so that the glass substrate 11 is exposed from the split window 121 e in the thin-film layer 12. The solar cell 2 is disposed on the substrate 1, and includes the first electrode layer 21, the active layer 22 and the second electrode layer 23. The first electrode layer 21 is disposed on the buffer layer 13′, and is patterned to form with the first split way w1. The active layer 22 is disposed on the first electrode layer active layer 22 simultaneously filling the entire space of the first split way w1 in the first electrode layer 21. The active layer 22 is patterned to form with the second split way w2. The second electrode layer 23 is disposed on the active layer 22 simultaneously filling the entire space of the second split way w2 in the active layer 22. The second electrode layer 23 is patterned to form with the third split way w3.

Preferably, the scope of the split window 121e is constituted by the first split way w1, the second split way w2 and the third split way w3.

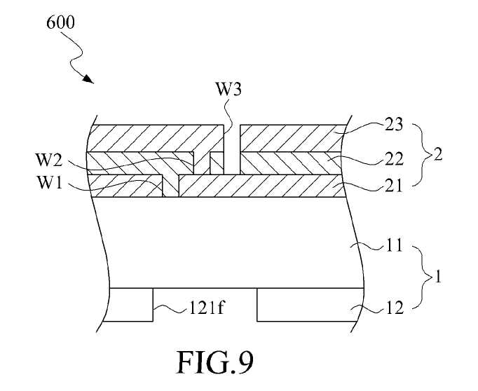

FIG. 9 shows a cross-sectional view of the sixth embodiment of the solar cell module of the present invention. As illustrated, the solar cell module 600 includes the substrate 1 and the solar cell 2. The substrate 1 is composed of the glass subtract 11 and the thin-film layer 12. The thin-film layer 12 is disposed on the glass substrate 11 and is patterned to form with the split window 121f for exposing the glass substrate 11. The solar cell 2 is disposed on the substrate 1, and includes the first electrode layer 21, the active layer 22 and the second electrode layer 23. The first electrode layer 21 is disposed on the glass substrate 11, and is patterned to form with the first split way w1. The active layer 22 is disposed on the first electrode layer active layer 22 simultaneously filling the entire space of the first split way w1 in the first electrode layer 21. The active layer 22 is patterned to form with the second split way w2. The second electrode layer 23 is disposed on the active layer 22 simultaneously filling the entire space of the second split way w2 in the active layer 22. The second electrode layer 23 is patterned to form with the third split way w3.

Preferably, the scope of the split window 121f is constituted by the first split way w1, the second split way w2 and the third split way w3.

As described above, since the thin-film layer is formed with the split window, which is constituted by at least one of the pre-formed split ways in the solar cell. Therefore, the direction of the high energy beam entering into the solar cell for conducting the splitting operation (patterning operation) is not obstructed. The parameterization of the high energy beam, such as wavelength range, is the same as entering into the solar cell module without the thin-film layer. In order words, the parameterization of the high energy beam is not altered. In addition, since the high energy beam enters the solar cell via the split window in the thin-film layer, a portion material of the solar cell is pushed outward or squeezed out due to melting, which, in turn, causes easily cleaning of the split ways and hence no waste is left behind in those split ways.

While the invention has been described in connection with what is considered the most practical and preferred embodiments, it is understood that this invention is not limited to the disclosed embodiments but is intended to cover various arrangements included within the spirit and scope of the broadest interpretation so as to encompass all such modifications and equivalent arrangements.

What is claimed is:

1. A solar cell module comprising:
a substrate including a thin-film layer formed with a split window; and
a solar cell disposed on said substrate and including a plurality of material layers and a plurality of split ways corresponding to said material layers;
wherein, a scope of said split window is constituted by at least one of said split ways.

2. The solar cell module according to claim 1, wherein said substrate further includes a transparent substrate with said thin-film layer being disposed on said transparent substrate such that said transparent substrate is exposed via said split window in said thin-film layer.

3. The solar cell module according to claim 2, wherein said substrate further includes a buffer layer disposed on said transparent substrate such that said buffer layer is sandwiched between said transparent substrate and said thin-film layer.

4. The solar cell module according to claim 1, wherein said material layers includes a first electrode layer, an active layer and a second electrode layer.

5. The solar cell module according to claim 4, wherein said split ways are constituted by a first split way formed in said first electrode layer, a second split way formed in said active layer and a third split way formed in said second electrode layer.

6. The solar cell module according to claim 1, wherein said thin-film layer includes at least one colored film, an anti-reflective film, a protection film or a reflective film.

7. A method for fabricating a solar cell module comprising the steps of:
(i) preparing a substrate including a transparent substrate and a thin-film layer formed on said transparent substrate;
(ii) conducting splitting process on said thin-film layer such that said thin-film layer is formed with a split window via which said transparent substrate is exposed; and
(iii) disposing a solar cell on said substrate, said solar cell including a plurality of material layers and a plurality of split ways corresponding to said material layers;
wherein, at least one of said split ways is formed due to melting action in said material layers when a high energy beam passes through said split window of said thin-film layer.

8. The solar cell module fabricating method according to claim 7, further comprising prior to the step (i), minor steps of disposing said thin-film layer on said transparent substrate and patterning said thin-film layer in order to form said split window in said thin-film layer.

9. The solar cell module fabricating method according to claim 7, wherein said material layers is formed by a first electrode layer, an active layer and a second electrode layer, and wherein during formation of said material layers, said high energy beam passes through said split window in said thin-film layer so as to cause melting action in said material layers, thereby forming at least one of said split ways.

10. The solar cell module fabricating method according to claim 7, wherein said thin-film layer consists of at least one colored film, an anti-reflective film, a protection film or a reflective film.
